(19) United States
(12) Patent Application Publication
(10) Pub. No.: US 2026/0141950 A1
(43) Pub. Date: May 21, 2026

(54) RESISTIVE RANDOM-ACCESS MEMORY STRUCTURE AND METHOD

(71) Applicant: GlobalFoundries U.S. Inc., Malta, NY (US)

(72) Inventors: Venkatesh Periyapatna Gopinath, Fremont, CA (US); Siva Kumar Chinthu, Bangalore (IN); Navneet K. Jain, Milpitas, CA (US); Suresh Pasupula, Andhra Predesh (IN)

(21) Appl. No.: 18/953,954

(22) Filed: Nov. 20, 2024

(51) Int. Cl. G11C 13/00

(52) U.S. Cl. CPC G11C 13/0069; G11C 13/0026; G11C 13/0097

(57) ABSTRACT

Disclosed are a memory structure and an operating method. The structure includes: bit cells in columns and rows with all bit cells; source lines (SLs) and bit lines (BLs) for the columns; word lines (WL) for the rows; and peripheral circuitry to facilitate memory operations in a bit cell located in a selected column and a selected row. The peripheral circuitry includes a BL biasing circuit that applies an appropriate BL voltage to the BL for a selected column to achieve a desired memory operation and applies a positive unselected BL voltage to BLs for all unselected columns at least during write operations. The peripheral circuitry also includes a SL biasing circuit that applies an appropriate SL voltage to the SL for the selected column to achieve the desired memory operation and applies a positive unselected SL voltage to the SLs for all unselected columns at least during write operations.

### BACKGROUND

The present disclosure relates to resistive random-access memories (RRAMs) and, more particularly, to embodiments of an RRAM structure and of a method of operating the RRAM structure.

RRAM structures include an array of RRAM cells (also referred to herein as bit cells) arranged in columns and rows. Each bit cell can be, for example, a one-transistor one-resistor (1T1R) memory cell. Bit cells in each column can be connected between a source line (SL) and a bit line (BL) for the column. Bit cells in each row can be connected to a word line (WL) for the row. For example, each bit cell in a given column and a given row can include: a programmable resistor (also referred to herein as a variable resistor) with a first terminal connected to the SL for the column and a second terminal opposite the first terminal; and an access transistor including: a first source/drain region connected to the second terminal of the programmable resistor; a second source/drain region connected to the BL for the column; and a gate connected to the WL for the row.

Write operations in an RRAM structure can include a forming operation, a programming operation (also referred to herein as a set operation), and an erasing operation (also referred to herein as a reset operation). During a forming operation, the resistance state of the programmable resistor of a selected bit cell is switched from an initial very high resistance state (iHRS) (e.g., 10 megaohms (MΩ)), as seen immediately after manufacturing, to an operational resistance state that is lower than the iHRS (e.g., to an operational high resistance state (HRS) or to an operational resistance state (LRS)). The HRS (e.g., 100 kilohms (kΩ)) can be used to store, for example, a logic “0” and the LRS (e.g., 10 kΩ) can be used to store, for example, a logic “1.”

Consider the following example biasing conditions used to accomplish such write operations when the access transistors of the bit cells are N-type field effect transistors (NFETs). A forming operation directed to a selected bit cell can include: applying a high positive voltage (e.g., +2.5 volts (V)) to the WL connected to the selected bit cell; applying an even higher positive voltage (e.g., +4.0 V) to the SL connected to the selected bit cell; and connecting the BL connected to the selected bit cell to ground (e.g., to 0.0 V). For purposes of this disclosure, a high positive voltage is generally considered to be a positive voltage that is higher than that of the positive supply voltage (VDD) (e.g., VDD=0.8 V). A programming operation directed to a selected bit cell can include: applying a high positive voltage (e.g., 1.8 V) to the WL connected to the selected bit cell; applying a higher positive voltage (e.g., 2.5 V) to the WL connected to the selected bit cell; and connecting the BL connected to the selected bit cell to ground. An erasing operation directed to a selected bit cell can include: applying a high positive voltage (e.g., 2.5 V) to the WL connected to the selected bit cell; applying a high positive voltage (e.g., 2.5 V) to the BL connected to the selected bit cell; and connecting the SL connected to the selected bit cell to ground. Additionally, during each of these write operations, all other WLs, SLs and BLs that are not connected to the selected bit cell are also connected to ground. Unfortunately, such biasing conditions can result in undue stress on the access transistors within unselected bit cells in the same row as a selected bit cell. For example, gates of access transistors of unselected bit cells in the same row as a selected bit cell will receive a high positive word line voltage (e.g., 1.8 V or above) depending upon the type of write operation. However, since the SL and BL connected to each unselected bit cell in the same row as the selected bit cell will be connected to ground (i.e., at 0.0 V), the gate-to-source voltage (VGS) and the gate-to-drain voltage (VGD) of these access transistors will be high (e.g., each at 1.8 V or above). Extra gate dielectric (EG) transistors (i.e., transistors having a relatively thick gate dielectric layer) may be used as the access transistors in the bit cells to accommodate the high VGS and VDS conditions. However, such EG transistors are larger and have reduced drive strength as compared to standard gate dielectric (SG) transistors (i.e., transistors with a standard thickness gate dielectric layer).

### SUMMARY

Disclosed herein are embodiments of a resistive random-access memory (RRAM) structure. Generally, the structure can include an array of bit cells in columns and rows; bit lines for the columns; and a bit line biasing circuit connected to the bit lines. The bit line biasing circuit can be configured to apply specific bit line voltages to the bit lines to perform a memory operation in a bit cell in a selected column and a selected row. Furthermore, when the memory operation is a write operation of multiple possible write operations, the bit line biasing circuit can specifically apply a positive unselected bit line voltage to all bit lines for all unselected columns. The structure can also include source lines for the columns and a source line biasing circuit connected to the source lines. The source line biasing circuit can, optionally, also be configured to apply specific source line voltages to the source lines during performance of the memory operation. Furthermore, like the bit line biasing circuit, when the memory operation is a write operation, the source line biasing circuit can specifically apply a positive unselected source line voltage to all source lines for all unselected columns.

In some embodiments, the structure can include an array of bit cells in columns and rows and source lines and bit lines for the columns. Each bit cell can include a programmable resistor and an N-type field effect transistor (NFET) connected in series between a source line-bit line pair for a corresponding column. The bit line biasing circuit can be configured to apply specific bit line voltages to the bit lines to perform a memory operation in a bit cell in a selected column and a selected row. Furthermore, when the memory operation is a write operation of multiple possible write operations, the bit line biasing circuit can specifically apply a positive unselected bit line voltage to all bit lines for all unselected columns. The structure can also include a source line biasing circuit connected to the source lines. The source line biasing circuit can, optionally, also be configured to apply specific source line voltages to the source lines during performance of the memory operation. Furthermore, like the bit line biasing circuit, when the memory operation is a write operation, the source line biasing circuit can specifically apply a positive unselected source line voltage to all source lines for all unselected columns.

In some embodiments, the structure can include an array of bit cells in columns and rows and source lines and bit lines for the columns. Each bit cell can include a programmable resistor and a P-type field effect transistor (PFET) connected in series between a source line-bit line pair for a corresponding column. The bit line biasing circuit can be configured to apply specific bit line voltages to the bit lines to perform a memory operation in a bit cell in a selected column and a selected row. Furthermore, when the memory operation is a write operation of multiple possible write operations, the bit line biasing circuit can specifically apply a positive unselected bit line voltage to all bit lines for all unselected columns. The structure can also include a source line biasing circuit connected to the source lines. The source line biasing circuit can, optionally, also be configured to apply specific source line voltages to the source lines during performance of the memory operation. Furthermore, like the bit line biasing circuit, when the memory operation is a write operation, the source line biasing circuit can specifically apply a positive unselected source line voltage to all source lines for all unselected columns.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWING

The present disclosure will be better understood from the following detailed description with reference to the drawings, which are not necessarily drawn to scale and in which:

FIG. 1A is a schematic diagram illustrating disclosed embodiments of a resistive random-access memory (RRAM) structure;

FIGS. 1B-1 and 1B-2 are schematic diagrams illustrating different examples, respectively, of a bit cell that could be incorporated into the structure of FIG. 1;

FIGS. 2A-2D are cross-section diagrams illustrating an example bit cell and different resistance states, respectively, of a programmable resistor within the bit cell;

FIG. 3 is a table illustrating examples of sets of bias voltages for different memory operations when the access transistor of a bit cell is an N-type field effect transistor; and

FIG. 4 is a table illustrating examples of sets of bias voltages for different memory operations when the access transistor of a bit cell is a P-type field effect transistor.

### DETAILED DESCRIPTION

As mentioned above, typical biasing conditions employed during write operations in an RRAM structure can result in undue stress (e.g., due to high VGS and VGD conditions) on access transistors within unselected bit cells in the same row as a selected bit cell. EG transistors may be used as the access transistors in the bit cells to accommodate the high VGS and VGD conditions. However, such EG transistors are generally larger and have reduced drive strength as compared to SG transistors.

In view of the foregoing, disclosed herein are embodiments of a resistive random-access memory (RRAM) structure configured for optimal power, performance, and area (PPA) and a method of operating the RRAM structure. The RRAM structure can include an array of RRAM cells (hereinafter referred to as bit cells) arranged in columns and rows with all bit cells in a column connected between a source line (SL)-bit line (BL) pair for the column and with all bit cells in a row connected to a word line (WL) for the row. The RRAM structure can further include peripheral circuitry configured to facilitate the performance of memory operations including write operations (e.g., forming, programming, and erasing operations) and read operations in a bit cell in a selected column and selected row, while minimizing the occurrence of undue stress on the access transistors of bit cells contained in unselected columns during such memory operations. Specifically, the RRAM structure can include a BL biasing circuit that not only applies an appropriate BL voltage to the BL for the selected column to achieve the desired memory operation, but also applies a positive mid-level unselected BL voltage to BLs for all unselected columns (e.g., at least during write operations). Similarly, the RRAM structure can include a SL biasing circuit that not only applies an appropriate SL voltage to the SL for the selected column to achieve the desired memory operation, but also applies a positive mid-level unselected SL voltage to the SLs for all unselected columns (e.g., again at least during write operations). Using the positive unselected bit line voltage and the positive unselected source line voltage effectively reduces the VGS and VGD conditions in the access transistors of those bit cells that are located in unselected columns but happen to also be located in the selected row (as compared to if the bit lines and source lines of the unselected columns were simply discharged to ground), thereby effectively reducing undue stress on the access transistors as well as reducing leakage current (and, thus, power consumption). Additionally, as a result of lower stress, low voltage SG transistors can be employed for the access transistors of bit cells in the RRAM structure as opposed to high voltage EG transistors. By using such SG transistors, the bit error rate (BER) can be improved due to improved transistor drive strength and area of the RRAM structure due to the smaller size of SG transistors as compared to EG transistors.

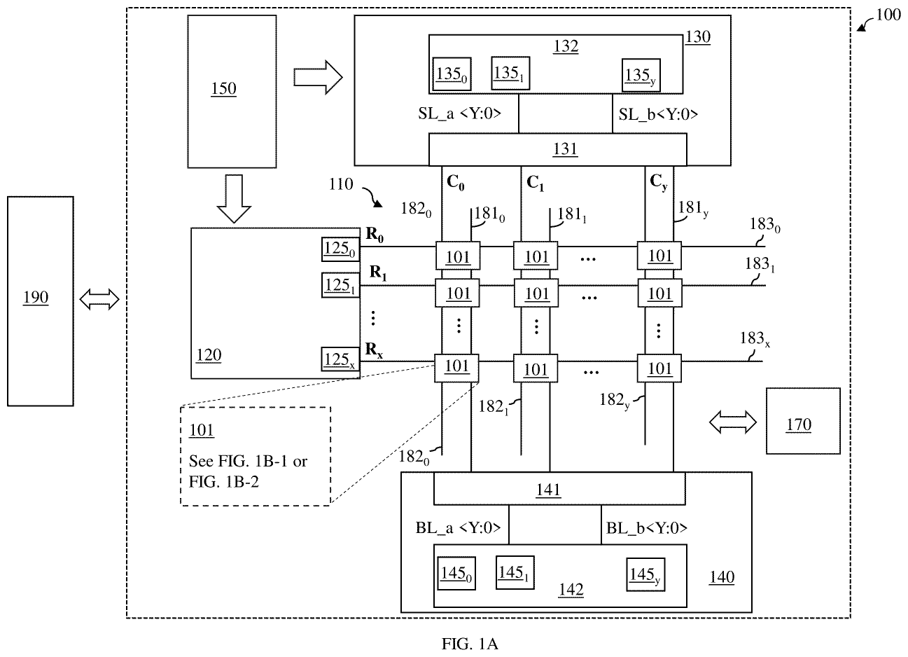

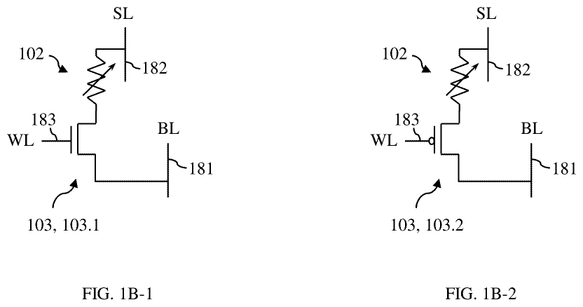

More particularly, FIG. 1A is a schematic diagram illustrating disclosed embodiments of a resistive random-access memory (RRAM) structure (hereinafter referred to as structure 100).

Structure 100 can include an array 110 of RRAM cells 101 (hereinafter referred to as bit cells) arranged in columns (C0-Cy) and rows (R0-Rx). Structure 100 can further include bit lines (BLs) 181₀-181_{y} for the columns (C0-Cy), respectively; source lines (SLs) 182₀-182_{y} for the columns (C0-Cy), respectively; and word lines (WLs) 183₀-183ₓ for the rows (R0-Rx), respectively. In one example, within structure 100, array 110 could include 4864 columns (i.e., C0-C4863) and 512 rows (i.e., R0-R511) of bit cells 101. Optionally, such an array 110 can be partitioned into multiple zones (e.g., 8 zones, each with 4864 columns and 512 rows). In any case, within array 110, all bit cells 101 in the same column can be connected to a corresponding SL-BL pair for that column. Additionally, all bit cells 101 in the same row can be connected to a corresponding WL for that row.

Structure 100 can further include a controller 190 and, in communication with controller 190, peripheral circuitry connected to BLs 181₀-181_{y}, to SLs 182₀-182_{y} and to WLs 183₀-183ₓ to facilitate the performance of memory operations including write operations (e.g., forming, programming, and erasing operations) and read operations. The peripheral circuitry can include components for establishing specific biasing conditions on BLs 181₀-181_{y}, SLs 182₀-182_{y} and WLs 183₀-183ₓ during the memory operation. Specifically, the peripheral circuitry can include, but is not limited to, at least one voltage generation block 150 and various biasing circuits (also referred to herein as decode blocks). The biasing circuits can include, for example: a WL biasing circuit 120 (also referred to herein as a WL decode block); a BL biasing circuit 140 (also referred to herein as a BL decode block); and a SL biasing circuit 130 (also referred to herein as a SL decode block).

Voltage generation block 150 can include one or more charge pumps or other voltage generation circuits suitable for generating voltages at various different levels required for memory operations (as discussed in greater detail below). Voltage generation blocks for memory structures are known in the art and, thus, specific details thereof have been omitted from this specification in order to allow the reader to focus on the salient aspects of the disclosed embodiments.

WL biasing circuit 120 can be connected to voltage generation block 150 and can include, for example, WL drivers 125₀-125ₓ electrically connected to WLs 183₀-183ₓ, respectively. SL biasing circuit 130 can be connected to voltage generation block 150 and can include, for example, a SL multiplexer (SL MUX) 131 electrically connected to SLs 182₀-182_{y} and to a SL driver block 132. SL driver block 132 can include SL drivers selectively connectable to SLs 182₀-182_{y} through SL MUX 131. For purpose of illustration, SL driver block 132 is shown as including y+1 SL drivers (see SL drivers 135₀-135_{y}). BL biasing circuit 140 can be connected to voltage generation block 150 and can include, for example, a BL multiplexer (BL MUX) 141 electrically connected to BLs 181₀-181_{y} and to a BL driver block 142. BL driver block 142 can include BL drivers selectively connectable to a BL through BL MUX 141. For purpose of illustration, BL driver block 142 is shown as including y+1 BL drivers (see BL drivers 145₀-145_{y}).

These biasing circuits 120, 130, 140 can be connected to receive control signals (e.g., row or column address signals, as appropriate, from controller 190 and, optionally, via a corresponding pre-decoder (not shown)) configured to decode those signals. These biasing circuits 120, 130, 140 can further be configured to receive specific bias voltages from voltage generation block 150 and, based on the decoded address signals, cause drivers contained therein to selectively apply specific bias voltages to BLs 181₀-181_{y}, to SLs 182₀-182_{y} and to WLs 183₀-183ₓ. Biasing circuits (i.e., decode blocks) that apply different bias voltages on the WLs, BLs, and SLs in an RRAM structure during a memory operation directed to a bit cell in a selected column and a selected row are known in the art. Those skilled in the art will recognize that such biasing circuits can be modified, as necessary, to establish the unique biasing conditions, which are employed in the disclosed embodiments and which are discussed in greater detail below.

The peripheral circuitry can also include a sense circuit 170, which is connected to BLs 181₀-181_{y} (or, alternatively, to SLs 182₀-182_{y}) and which includes one or more sense amplifiers. Sense circuit 170 can be configured to determine a stored data value in a selected bit cell during a read operation by using a sense amplifier to sense a change in an electrical parameter (e.g., voltage or current) on the BL (or SL), which is connected to the selected bit cell. Voltage generation blocks for memory structures are known in the art and, thus, specific details thereof have been omitted from this specification in order to allow the reader to focus on the salient aspects of the disclosed embodiments.

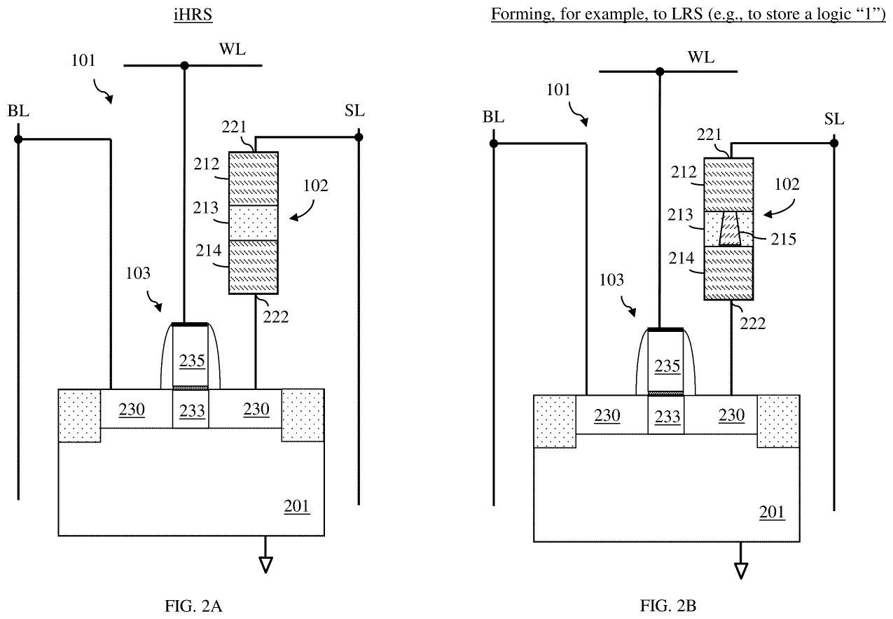

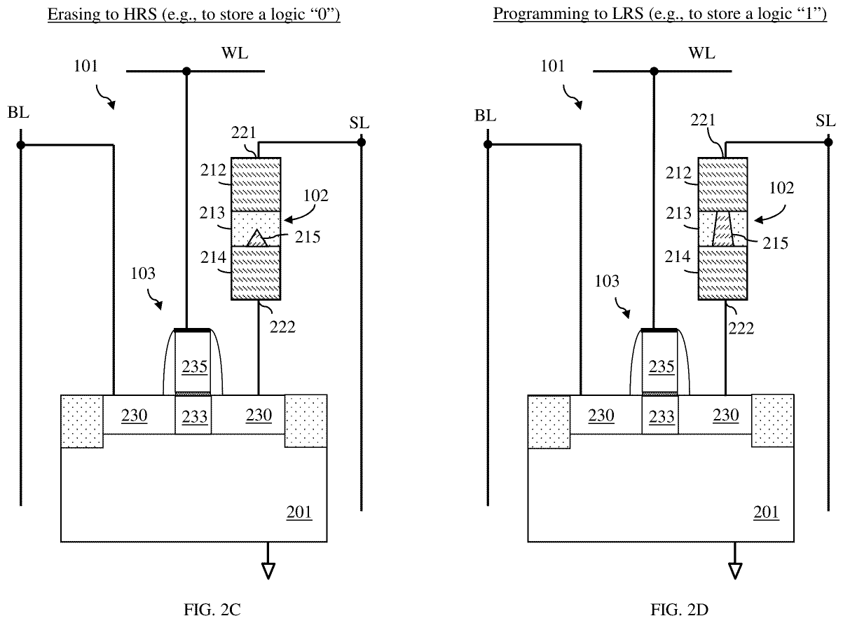

FIGS. 1B-1 and 1B-2 are schematic diagrams illustrating examples of a bit cell 101 that can be incorporated into array 110 of FIG. 1A. As illustrated in FIG. 1B-1 or FIG. 1B-2, each bit cell 101 can include a programmable resistor 102 (also referred to herein as a variable resistor) and an access transistor 103. Programmable resistor 102 can be a resistive random-access memory-type programmable resistor (e.g., a memristor or other resistive random-access memory-type programmable resistors). Access transistor 103 can be a field effect transistor (FET). In some embodiments, access transistor 103 can be an N-type field effect transistor (NFET) 103.1 (e.g., see FIG. 1B-1). In other embodiments, access transistor 103 can be a P-type field effect transistor (PFET) 103.2 (e.g., see FIG. 1B-2). In any case, in a given column, programmable resistor 102 and access transistor 103 (either an NFET access transistor 103.1 or a PFET access transistor 103.2) can be electrically connected in series between a SL 182 and a BL 181 for that given column. Furthermore, in a given row, all gates of all access transistors 103 of all bit cells 101 in the given row can be electrically connected to the WL 183 for that given row.

FIGS. 2A-2D are cross-section diagrams illustrating, in greater detail, a bit cell 101 including a programmable resistor 102 and an access transistor 103 (e.g., either an NFET access transistor 103.1 or a PFET access transistor 103.2) connected in series between a SL 182 and a BL 181. FIGS. 2A-2D further illustrate different resistance states, respectively, of programmable resistor 102 within bit cell 101.

Referring to FIGS. 2A-2D, as mentioned above, access transistor 103 can be FET, such as an NFET or a PFET. Specifically, access transistor 103 can include source/drain regions 230 and a channel region 233 between source/drain regions 230. Those skilled in the art will recognize that, in the case of an NFET access transistor, source/drain regions 230 can be N-type source/drain regions, which are doped so as to have N-type conductivity at a relatively high conductivity level. That is, in an NFET access transistor, source/drain regions 230 can be N+ source/drain regions. Additionally, in the case of an NFET access transistor, channel region 233 can be doped so as to have P-type conductivity at a relatively low conductivity level or can be undoped. That is, in an NFET access transistor, channel region 233 can be a P-channel region or an intrinsic channel region. Those skilled in the art will also recognize that, in the case of a PFET access transistor, source/drain regions 230 can be P-type source/drain regions, which are doped so as to have P-type conductivity at a relatively high conductivity level. That is, in a PFET access transistor, source/drain regions 230 can be P+ source/drain regions. Additionally, in the case of a PFET access transistor, channel region 233 can be doped so as to have N-type conductivity at a relatively low conductivity level or undoped. That is, in a PFET access transistor, channel region 233 can be an N-channel region or an intrinsic channel region. In any case, access transistor 103 can further include a gate 235 adjacent to channel region 233.

In some embodiments, access transistor 103 could be on a bulk semiconductor substrate 201, as illustrated. In other embodiments, access transistor 103 could be formed using a semiconductor-on-insulator processing technology (e.g., an partially depleted silicon-on-insulator (PDSOI) processing technology or a fully depleted silicon-on-insulator (FDSOI) processing technology. That is, channel region 233 could be positioned laterally within a semiconductor layer on an insulator layer above a semiconductor substrate. It should be understood that configuration of the access transistor shown in FIGS. 2A-2D is provided for illustration purposes and is not intended to be limiting. Any suitable now known or subsequently developed transistor could be incorporated into bit cell 101 for use as an access transistor.

Also, as mentioned above, programmable resistor 102 can be a resistive random-access memory-type programmable resistor (e.g., a memristor or other resistive random-access memory-type programmable resistors). Specifically, programmable resistor 102 can have two terminals (i.e., a first terminal 221 and a second terminal 222). In some embodiments, programmable resistor 102 can be a back end of the line (BEOL) multi-layer structure and, particularly, a BEOL metal-insulator-metal (MIM) structure. The MIM structure can include a first metal layer 212 (at first terminal 221). First metal layer 212 can include one or more layers of metal or metal alloy materials (e.g., titanium, titanium nitride and/or any other suitable metal or metal alloy material). The MIM structure can further include a second metal layer 214 (at second terminal 222). The second metal layer 214 can include one or more layers of metal or metal alloy materials (e.g., titanium, titanium nitride and/or any other suitable metal or metal alloy material). The MIM structure can further include an insulator layer 213 (also referred to as a switching layer) stacked between the two metal layers 212 and 214 and including one or more layers of isolation material (e.g., hafnium oxide and/or any other suitable insulator material).

First terminal 221 of programmable resistor 102 can be electrically connected to the SL for the column containing the bit cell 101. Second terminal 222 of programmable resistor 102 can be electrically connected to one source/drain region 230 of access transistor 103. The other source/drain region 230 of access transistor 103 can be electrically connected to the BL for the column containing the bit cell. Thus, programmable resistor 102 and access transistor 103 are electrically connected in series between the SL and the BL for the same column. Additionally, gate 235 of access transistor 103 can be connected to the WL for the row containing the bit cell.

It should be noted that, because of the unique biasing conditions disclosed herein and to be employed on the WLs, BLs, and SLs in array 110 during a write operation (e.g., a forming operation, a programming operation, or an erasing operation) directed to a bit cell 101 located within a selected column and selected row (including, e.g., using relatively low positive BL and SL voltages on the BLs and SLs for all unselected columns), access transistor 103 can be a low voltage device, which is relatively small in size. For example, access transistor 103 could be a low threshold voltage (LVT), standard gate dielectric (SG) transistor with a relatively low maximum voltage rating (e.g., a 0.8 V LVT FET), a channel width of 160 nanometers (nm), and a channel length of 40 nm.

As illustrated in FIG. 2A, the post-manufacture resistance state of programmable resistor 102 can be an initial high resistance state (iHRS). iHRS can, for example, be approximately 100 megaohms (MΩ) or higher. During a forming operation directed to a bit cell located in a selected column and a selected row, a specific set of bias voltages can be established on the WL for the selected row and on the SL and BL for the selected column to switch programmable resistor 102 to an operational state that is lower than iHRS. Programmable resistor 102 can have, for example, two operational states including an operational high resistance state (HRS) (e.g., of approximately 50 kilohms (kΩ)) for storing a first logic value (e.g., a logic “0”) and an operational low resistance state (LRS) (e.g., of approximately 5 kΩ) for storing a second logic value (e.g., a logic “1”). For purposes of illustration, the forming operation described herein is employed to change the resistance state from iHRS to LRS to store the second logic value. Thus, as illustrated in FIG. 2B, during the forming operation, the specific set of bias voltages on the WL for the selected row and on the SL and BL for the selected column can be employed to initiate metal ion migration through insulator layer 213. Such metal ion migration can result in the formation of conductive filament(s) 215 that extend through insulator layer 213 between metal layers 212 and 214, thereby reducing the resistance state of the programmable resistor 102 from iHRS to LRS to store the second logic value (e.g., logic “1”).

As illustrated in FIG. 2C, during an erasing operation (also referred to herein as a resetting operation) directed to a bit cell in a selected row and a selected column, another specific set of bias voltages on the WL for the selected row and on the SL and BL for the selected column to change the direction of metal ion migration through insulator layer 213 in order to break up conductive filament(s) 215 (e.g., so that they only extend partially through insulator layer 213 between metal layers 212 and 214) in programmable resistor 102 to again store the first logic value (e.g., logic “0”).

As illustrated in FIG. 2D, during a programming operation (also referred to herein as a setting operation) directed to a bit cell in a selected row and a selected column, yet another specific set of bias voltages on the WL for the selected row and the SL and BL for the selected column can be employed to again cause metal ion migration through insulator layer 213 to increase the numbers and/or lengths of conductive filament(s) 215 extending through insulator layer 213 between and contacting metal layers 212 and 214 (e.g., so that metal layers 212 and 214 are electrically connected), as illustrated, in order to store the second logic value (e.g., logic “1”).

It should be noted that the specific sets of bias voltages employed during any of the above-mentioned write operations directed to a bit cell located in a selected column and a selected row will depend on: (1) the type of memory operation (e.g., forming, programming, or erasing); (2) whether the access transistors 103 in the bit cells 101 are NFETs 103.1 (as shown in FIG. 1B-1) or PFETs 103.2 (as shown in FIG. 1B-2); and (3) whether a given WL is for the selected row or for an unselected row, whether a given SL is for the selected column or for an unselected column, and whether a given BL is for the selected column or for an unselected column. In some embodiments, a specific set of bias voltages employed during a read operation directed to a bit cell in a selected column and a selected row can also depend on whether the access transistors 103 in the bit cells 101 are NFETs 103.1 (as shown in FIG. 1B-1) or PFETs 103.2 (as shown in FIG. 1B-2) and also whether a given WL is for the selected row or for an unselected row, whether a given SL is for the selected column or for an unselected column, and whether a given BL is for the selected column or for an unselected column.

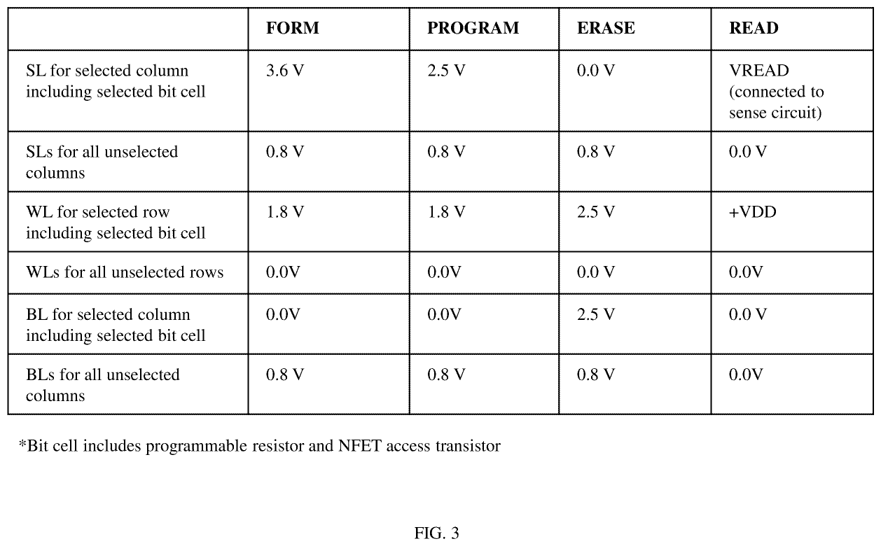

FIG. 3 is a table illustrating examples of sets of bias voltages for the WLs, BLs, and SLs during different memory operations performed, for example, in structure 100 when the access transistors 103 in bit cells 101 are NFETs 103.1 (e.g., as shown in FIG. 1B-1). In some embodiments, these NFET access transistors can be, for example, 0.8-V SG transistors and the power supply voltage (VDD) for structure 100 can also be 0.8 V. For purposes of illustration, such memory operations are described below as being directed to a bit cell 101 located in a selected column (e.g., C0) and a selected row (e.g., R0). In this case, C1-Cy are unselected columns and R1-Rx are unselected rows.

For a forming operation to switch the resistance state of the programmable resistor 102 in the bit cell 101 located in the selected column C0 and the selected row R0 from an initial high resistance state (iHRS) (e.g., 10 MΩ) to a low resistance state (LRS) (e.g., 10 kΩ) or, alternatively, to an operational high resistance state (HRS) (e.g., 100 kΩ), WL biasing circuit 120 can cause WL driver 125₀ for selected row R0 to apply a positive selected WL voltage (e.g., a 1.8 V selected WL voltage) to WL 183₀ for selected row R0 so as to switch the access transistor 103.1 (an NFET) in the bit cell 101 at issue to an ON state and can further cause all other WLs 183₁-183x for all unselected rows R1-Rx to be discharged to ground (e.g., to 0.0 V). BL biasing circuit 140 can cause BL drivers 145₁-145y to apply a positive unselected BL voltage (e.g., a 0.8 V unselected BL voltage) to BLs 181₁-181y for all unselected columns C1-Cy via BL MUX 141 and can further cause BL 181₀ for selected column C0 to be discharged to ground (e.g., 0.0 V). Furthermore, SL biasing circuit 130 can cause SL drivers 135₁-135y to apply a positive unselected SL voltage (e.g., a 0.8 V unselected SL voltage) to SLs 182₁-182y for the unselected columns C1-Cy via SL MUX 131 and can further cause SL driver 135₀ to apply a positive selected SL voltage (e.g., a 3.6 V selected SL voltage) (which is specifically higher than the positive unselected SL voltage) to SL 182₀ for selected column C0 also via SL MUX 131.

For an erasing operation to switch the resistance state of the programmable resistor 102 in the bit cell 101 located in the selected column C0 and the selected row R0 from the LRS (e.g., 10 kΩ) to HRS (e.g., 100 kΩ), WL biasing circuit 120 can cause WL driver 125₀ for selected row R0 to apply an additional positive selected WL voltage (e.g., a 2.5 V selected WL voltage) (which is specifically higher than the positive selected WL voltage used during forming) to WL 183₀ for selected row R0 to switch the access transistor 103.1 (an NFET) of the bit cell 101 at issue to an ON state and can further cause all other WLs 183₁-183x for all unselected rows R1-Rx to be discharged to ground (e.g., to 0.0 V). BL biasing circuit 140 can cause BL drivers 145₁-145y to apply the positive unselected BL voltage (e.g., the 0.8 V unselected BL voltage) to BLs 181₁-181y for all unselected columns C1-Cy via BL MUX 141 and can further cause BL driver 145₀ to apply a positive selected BL voltage (e.g., a 2.5 V selected BL voltage) (which is specifically higher than the positive unselected BL voltage) to BL 181₀ for selected column C0 also via BL MUX 141. Furthermore, SL biasing circuit 130 can cause SL drivers 135₁-135y to apply the positive unselected SL voltage (e.g., the 0.8 V unselected SL voltage) to SLs 182₁-182y for the unselected columns C1-Cy via SL MUX 131 and can further cause SL 182₀ for selected column C0 to be discharged to ground (e.g., 0.0 V).

For a programming operation to switch the resistance state of the programmable resistor 102 of the bit cell 101 located in the selected column C0 and the selected row R0 from HRS (e.g., 100 kΩ) to LRS (e.g., 10 kΩ), WL biasing circuit 120 can cause WL driver 125₀ for selected row R0 to apply the positive selected WL voltage (e.g., the 1.8 V selected WL voltage) to WL 183₀ for selected row R0 to switch the access transistor 103.1 (an NFET) of the bit cell 101 at issue to an ON state and can further cause all other WLs 183₁-183x for all unselected rows R1-Rx to be discharged to ground (e.g., to 0.0 V). BL biasing circuit 140 can cause BL drivers 145₁-145y to apply the positive unselected BL voltage (e.g., the 0.8 V unselected BL voltage) to BLs 181₁-181y for all unselected columns C1-Cy via BL MUX 141 and can further cause BL 181₀ for selected column C0 to be discharged to ground (e.g., 0.0 V). SL biasing circuit 130 can cause SL drivers 135₁-135y to apply the positive unselected SL voltage (e.g., a 0.8 V unselected SL voltage) to SLs 182₁-182y for the unselected columns C1-Cy via SL MUX 131 and can further cause SL driver 135₀ to apply an additional positive selected SL voltage (e.g., a 2.5 V positive selected SL voltage) (which is specifically between the positive unselected SL voltage and the positive selected SL voltage) to SL 182₀ for selected column C0 also via SL MUX 131.

For a read operation directed to bit cell 101 located in the selected column C0 and the selected row R0, WL biasing circuit 120 can cause WL driver 125₀ for selected row R0 to apply yet another positive selected WL voltage (e.g., at VDD+) to WL 183₀ for selected row R0 to switch the access transistor 103.1 (an NFET) of the bit cell 101 at issue to an ON state and can further cause all other WLs 183₁-183x for all unselected rows R1-Rx to be discharged to ground (e.g., to 0.0 V). BL biasing circuit 140 can cause all BLs for all columns C0-Cy to be discharged to ground (e.g., 0.0 V). SL biasing circuit 130 can cause SL driver 135₀ to apply a positive read voltage (VREAD) to SL 182₀ for selected column C0 via SL MUX 131 and can further cause all other SLs 182₁-182x for all unselected rows R1-Rx to be discharged to ground.

It should be noted that in the above example the maximum difference between the unselected BL voltage (e.g., of 0.8 V), which is applied to bit lines for unselected columns during an erasing operation, and the selected BL voltage (e.g., 2.5 V), which is applied to the BL for the selected column during the erasing operation, is reduced (e.g., as compared to prior art erasing operations wherein BLs for unselected columns are at ground). Additionally, the maximum difference between the unselected SL voltage (e.g., of 0.8 V), which is applied to SLs for unselected columns during a programming operation, and the selected SL voltage (e.g., 2.5 V), which is applied to the SL for the selected column during the programming operation, is also reduced (e.g., as compared to prior art programming operations wherein SLs for unselected columns are at ground). As a result, BL drivers 145₀-145_{y} and SL drivers 135₀-135_{y} need to support voltage levels from 0.8 V to 2.5 V (and not voltage levels from 0.0 V to 2.5 V). Thus, these drivers can be simplified and specifically can include a fewer FETs (e.g., two FETs as compared to six FETs) for area savings. Similarly, BL MUX 141 and SL MUX 131 can also be simplified to include fewer FETs for even greater area savings.

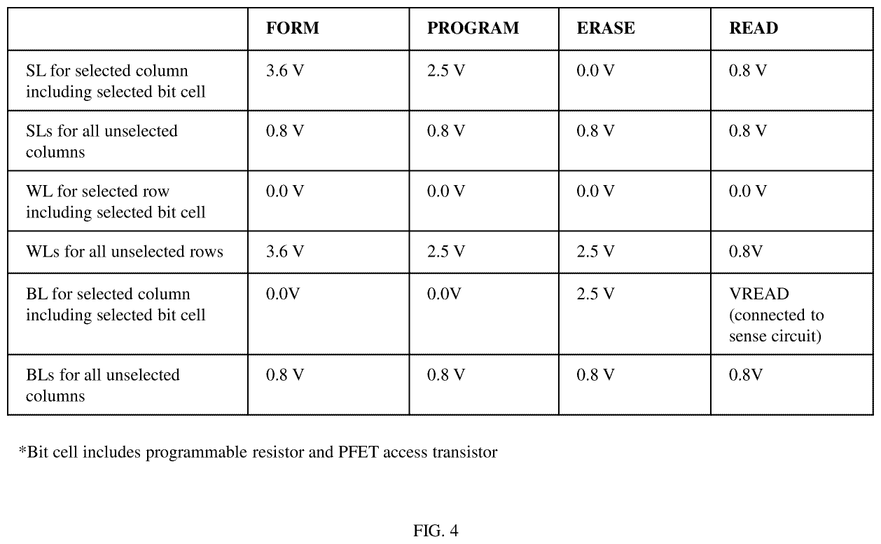

FIG. 4 is a table illustrating examples of sets of bias voltages for the WLs, BLs, and SLs during different memory operations performed, for example, a structure 100 when the access transistors in bit cells 101 are PFETs 103.2 (e.g., as shown in FIG. 1B-2). In some embodiments, these PFET access transistors can be, for example, 0.8-V SG transistors and the power supply voltage (VDD) for structure 100 can also be 0.8 V. For purposes of illustration, such memory operations are described below as being directed to a bit cell 101 located in a selected column (e.g., C0) and a selected row (e.g., R0). In this case, C1-Cy are unselected columns and R1-Rx are unselected rows.

For a forming operation to switch the resistance state of the programmable resistor 102 in the bit cell 101 located in the selected column C0 and the selected row R0 from an initial high resistance state (iHRS) (e.g., 10 MΩ) to a low resistance state (LRS) (e.g., 10 kΩ) or, alternatively, to an operational high resistance state (HRS) (e.g., 100 kΩ), WL biasing circuit 120 can cause WL 183₀ for selected row R0 to be discharged to ground (e.g., to 0.0 V) to switch the access transistor 103.2 (a PFET) of the bit cell 101 at issue to an ON state and can further cause WL drivers 125₁-125x to apply an positive unselected WL voltage (e.g., a 3.6 V unselected WL voltage) to WLs 183₁-183x for all unselected rows R1-Rx. BL biasing circuit 140 can cause BL drivers 145₁-145y to apply a positive unselected BL voltage (e.g., a 0.8 V unselected BL voltage) to BLs 181₁-181y for all unselected columns C1-Cy via BL MUX 141 and can further cause BL 181₀ for selected column C0 to be discharged to ground (e.g., 0.0 V). Furthermore, SL biasing circuit 130 can cause SL drivers 135₁-135y to apply a positive unselected SL voltage (e.g., a 0.8 V unselected SL voltage) to SLs 182₁-182y for the unselected columns C1-Cy via SL MUX 131 and can further cause SL driver 135₀ to apply a positive selected SL voltage (e.g., a 3.6 V selected SL voltage) (which is specifically higher than the positive unselected SL voltage) to SL 182₀ for selected column C0 also via SL MUX 131.

For an erasing operation to switch the resistance state of the programmable resistor 102 in the bit cell 101 located in the selected column C0 and the selected row R0 from the LRS (e.g., 10 kΩ) to HRS (e.g., 100 kΩ), WL biasing circuit 120 can cause WL 183₀ for selected row R0 to be discharged to ground to switch the access transistor 103.2 (a PFET) of the bit cell 101 at issue to an ON state and can further cause WL drivers 125₁-125x to apply an additional positive unselected WL voltage (e.g., a 2.5 V unselected WL voltage) (which is specifically lower than the positive unselected WL voltage used during the forming operation) to WLs 183₁-183x for all unselected rows R1-Rx. BL biasing circuit 140 can cause BL drivers 145₁-145y to apply the positive unselected BL voltage (e.g., the 0.8 V unselected BL voltage) to BLs 181₁-181y for all unselected columns C1-Cy via BL MUX 141 and can further cause BL driver 145₀ to apply a positive selected BL voltage (e.g., a 2.5 V selected BL voltage) (which is specifically higher than the positive unselected BL voltage) to BL 181₀ for selected column C0 also via BL MUX 141. Furthermore, SL biasing circuit 130 can cause SL drivers 135₁-135y to apply the positive unselected SL voltage (e.g., the 0.8 V unselected SL voltage) to SLs 182₁-182y for the unselected columns C1-Cy via SL MUX 131 and can further cause SL 182₀ for selected column C0 to be discharged to ground (e.g., 0.0 V).

For a programming operation to switch the resistance state of the programmable resistor 102 of the bit cell 101 located in the selected column C0 and the selected row R0 from HRS (e.g., 100 kΩ) to LRS (e.g., 10 kΩ), WL biasing circuit 120 can cause WL 183₀ for selected row R0 to be discharged to ground (e.g., 0.0 V) to switch the access transistor 103.2 (a PFET) of the bit cell 101 at issue to an ON state and can further cause WL drivers 125₁-125ₓ for the unselected rows R1-Rx to apply an additional positive unselected WL voltage (e.g., a 2.5 V unselected WL voltage) (which is specifically lower than the positive unselected WL voltage used during the forming operation) to WLs 183₁-183ₓ for the unselected rows R1-Rx. BL biasing circuit 140 can cause BL drivers 145₁-145y to apply the positive unselected BL voltage (e.g., the 0.8 V unselected BL voltage) to BLs 181₁-181y for all unselected columns C1-Cy via BL MUX 141 and can further cause BL 181₀ for selected column C0 to be discharged to ground (e.g., 0.0 V). SL biasing circuit 130 can cause SL drivers 135₁-135y to apply the positive unselected SL voltage (e.g., a 0.8 V unselected SL voltage) to SLs 182₁-182y for the unselected columns C1-Cy via SL MUX 131 and can further cause SL driver 135₀ to apply an additional positive selected SL voltage (e.g., a 2.5 V positive selected SL voltage) (which is specifically between the positive unselected SL voltage and the positive selected SL voltage) to SL 182₀ for selected column C0 also via SL MUX 131.

For a read operation directed to bit cell 101 located in the selected column C0 and the selected row R0, WL biasing circuit 120 can cause WL 183₀ for selected row R0 to be discharged to ground (e.g., 0.0 V) to switch the access transistor 103.2 (a PFET) of the bit cell 101 at issue to an ON state and can further cause WL drivers 125₁-125x to apply yet another positive unselected WL voltage (e.g., a 0.8 V unselected WL voltage) to WLs 183₁-183x for all unselected rows R1-Rx. BL biasing circuit 140 can cause BL driver 145₀ to apply a positive read voltage (VREAD) to BL 181₀ for selected column C0 via BL MUX 141 and can further cause BL drivers 145₁-145_{y} to apply the positive unselected BL voltage (e.g., the 0.8 V unselected BL voltage) to all BLs 181₁-181_{y} for all unselected columns C1-Cy also via BL MUX 141. SL biasing circuit 130 can cause SL drivers 135₀-135_{y} to apply the same positive SL voltage (e.g., a 0.8 V SL voltage) to all SLs 182₀-182_{y} for all columns via SL MUX 131.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
an array of bit cells in columns and rows;
bit lines for the columns; and
a bit line biasing circuit connected to the bit lines,
wherein the bit line biasing circuit is configured to apply specific bit line voltages to the bit lines to perform a memory operation in a bit cell in a selected column and a selected row, and
wherein, when the memory operation is a write operation of multiple possible write operations, the bit line biasing circuit applies a positive unselected bit line voltage to all bit lines for all unselected columns.

2. The structure of claim 1, further comprising:
source lines for the columns; and
a source line biasing circuit connected to the source lines,
wherein the source line biasing circuit is configured to apply specific source line voltages to the source lines to perform the memory operation, and
wherein, when the memory operation is the write operation, the source line biasing circuit applies a positive unselected source line voltage to all source lines for the unselected columns.

3. The structure of claim 2, wherein the positive unselected bit line voltage and the positive unselected source line voltage are equal.

4. The structure of claim 2, wherein each bit cell includes a programmable resistor and access transistor connected in in series between a source line-bit line pair for a corresponding column.

5. A structure comprising:
an array of bit cells in columns and rows;
source lines and bit lines for the columns, wherein each bit cell includes a programmable resistor and an N-type field effect transistor connected in series between a source line-bit line pair for a corresponding column; and
a bit line biasing circuit connected to the bit lines,
wherein the bit line biasing circuit is configured to apply specific bit line voltages to the bit lines to perform a memory operation in a bit cell in a selected column and a selected row, and
wherein, when the memory operation is a write operation of multiple possible write operations, the bit line biasing circuit applies a positive unselected bit line voltage to all bit lines for all unselected columns.

6. The structure of claim 5, further comprising a source line biasing circuit connected to the source lines,
wherein the source line biasing circuit is configured to apply specific source line voltages to the source lines to perform the memory operation, and
wherein, when the memory operation is the write operation, the source line biasing circuit applies a positive unselected source line voltage to all source lines for the unselected columns.

7. The structure of claim 6, wherein the positive unselected bit line voltage and the positive unselected source line voltage are equal.

8. The structure of claim 6, wherein the multiple possible write operations include any of a forming operation, a programming operation, and an erasing operation.

9. The structure of claim 8, further comprising: word lines for rows; and a word line biasing circuit connected to the word lines,
wherein, when the write operation is the forming operation, the word line biasing circuit applies a positive selected word line voltage to a word line for the selected row and further discharges all word lines for all unselected rows to ground, the bit line biasing circuit applies the positive unselected bit line voltage to the bit lines for all the unselected columns and discharges a bit line for the selected column to ground, and the source line biasing circuit applies the positive unselected source line voltage to the source lines for the unselected columns and applies a positive selected source line voltage that is higher than the positive unselected source line voltage to a source line for the selected column,
wherein, when the write operation is the programming operation, the word line biasing circuit applies the positive selected word line voltage to the word line for the selected row and further discharges the word lines for the unselected rows to ground, the bit line biasing circuit applies the positive unselected bit line voltage to the bit lines for the unselected columns and discharges the bit line for the selected column to ground, and the source line biasing circuit applies an additional positive selected source line voltage that is between the positive unselected source line voltage and the positive selected source line voltage to the source line for the selected column, and
wherein, when the write operation is the erasing operation, the word line biasing circuit applies an additional positive selected word line voltage that is higher than the positive selected word line voltage to the word line for the selected row and further discharges the word lines for the unselected rows to ground, the bit line biasing circuit applies the positive unselected bit line voltage to the bit lines for the unselected columns and applies a positive selected bit line voltage that is higher than the positive unselected bit line voltage to the bit line for the selected column, and the source line biasing circuit applies the positive unselected source line voltage to the source lines for the unselected columns and discharges the source line for the selected column to ground.

10. The structure of claim 8, further comprising: word lines for rows; and a word line biasing circuit connected to the word lines,
wherein a positive supply voltage is 0.8 volts (V),
wherein, when the write operation is the forming operation, the word line biasing circuit applies a 1.8 V selected word line voltage to a word line for the selected row and further discharges all word lines for all unselected rows to ground, the bit line biasing circuit applies a 0.8 V unselected bit line voltage to the bit lines for the unselected columns and discharges a bit line for the selected column to ground, and the source line biasing circuit applies a 0.8 V unselected source line voltage to the source lines for the unselected columns and applies a 3.6 V selected source line voltage to a source line for the selected column,
wherein, when the write operation is the programming operation, the word line biasing circuit applies the 1.8 V selected word line voltage to the word line for the selected row and further discharges the word lines for the unselected rows to ground, the bit line biasing circuit applies the 0.8 V unselected bit line voltage to the bit lines for the unselected columns and discharges the bit line for the selected column to ground, and the source line biasing circuit applies the 0.8 V unselected source line voltage to the source lines for the unselected columns and applies a 2.5 V selected source line voltage to the source line for the selected column, and
wherein, when the write operation is the erasing operation, the word line biasing circuit applies a 2.5 V selected word line voltage to the word line for the selected row and further discharges the word lines for the unselected rows to ground, the bit line biasing circuit applies the 0.8 V unselected BL voltage to the bit lines for the unselected columns and a 2.5 V selected bit line voltage to the bit line for the selected column, and the source line biasing circuit applies the 0.8 V unselected SL voltage to the source lines for the unselected columns and discharges the source line for the selected column to ground.

11. The structure of claim 5, wherein the programmable resistor is a resistive random-access memory-type programmable resistor.

12. The structure of claim 5, wherein the N-type field effect transistor is a 0.8-V transistor.

13. The structure of claim 5, wherein the N-type field effect transistor is a standard gate dielectric transistor.

14. A structure comprising:
columns and rows of bit cells;
source lines and bit lines for the columns, wherein each bit cell includes a programmable resistor and a P-type field effect transistor connected in series between a source line-bit line pair for a corresponding column;
a bit line biasing circuit connected to the bit lines
wherein the bit line biasing circuit is configured to apply specific bit line voltages to the bit lines to perform a memory operation in a bit cell in a selected column and a selected row, and
wherein, when the memory operation is a write operation of multiple possible write operations, the bit line biasing circuit applies a positive unselected bit line voltage to all bit lines for all unselected columns; and
a source line biasing circuit connected to the source lines,
wherein the source line biasing circuit is configured to apply specific source line voltages to the source lines to perform the memory operation, and
wherein, when the memory operation is the write operation, the source line biasing circuit applies a positive unselected source line voltage to all source lines for the unselected columns.

15. The structure of claim 14, wherein the positive unselected bit line voltage and the positive unselected source line voltage are equal.

16. The structure of claim 14, wherein the multiple possible write operations include any of a forming operation, a programming operation, and an erasing operation.

17. The structure of claim 16, further comprising: word lines for rows; and a word line biasing circuit connected to the word lines,
wherein, when the write operation is the forming operation, the word line biasing circuit discharges a word line for the selected row to ground and further applies a positive unselected word line voltage to all word lines for all unselected rows, the bit line biasing circuit applies the positive unselected bit line voltage to the bit lines for the unselected columns and discharges a bit line for the selected column to ground, and the source line biasing circuit applies the positive unselected source line voltage to the source lines for the unselected columns and applies a positive selected source line voltage that is greater than the positive unselected source line voltage to a source line for the selected column,
wherein, when the write operation is the programming operation, the word line biasing circuit discharges the word line for the selected row to ground and further applies an additional positive unselected word line voltage that is lower than the positive unselected word line voltage to the word lines for the unselected rows, the bit line biasing circuit applies the positive unselected bit line voltage to the bit lines for the unselected columns and discharges the bit line for the selected column to ground, and the source line biasing circuit applies the positive unselected source line voltage to the source lines for the unselected columns and applies an additional positive selected source line voltage that is between the positive unselected source line voltage and the positive selected source line voltage to the source line for the selected column, and
wherein, when the write operation is the erasing operation, the word line biasing circuit discharges the word line for the selected row to ground and further applies the additional positive unselected word line voltage to the word lines for the unselected rows, the bit line biasing circuit applies the positive unselected bit line voltage to the bit lines for the unselected columns and applies a positive selected bit line voltage that is higher than the positive unselected bit line voltage to the bit line for the selected column, and the source line biasing circuit applies the positive unselected source line voltage to the source lines for the unselected columns and discharges the source line for the selected column to ground.

18. The structure of claim 16, further comprising: word lines for rows; and a word line biasing circuit connected to the word lines,
wherein the P-type field effect transistor is a 0.8-volt (V) transistor,
wherein a positive supply voltage is 0.8 V,
wherein, when the write operation is the forming operation, the word line biasing circuit discharges a word line for the selected row to ground and further applies a 3.6 V unselected word line voltage to all word lines for all unselected rows, the bit line biasing circuit applies a 0.8 V positive unselected bit line voltage to the bit lines for the unselected columns and discharges a bit line for the selected column to ground, and the source line biasing circuit applies a 0.8 V positive unselected source line voltage to the source lines for the unselected columns and further applies a 3.6 V selected source line voltage to a source line for the selected column,
wherein, when the write operation is the programming operation, the word line biasing circuit discharges the word line for the selected row to ground and further applies a 2.5 V unselected word line voltage to the word lines for the unselected rows, the bit line biasing circuit applies the 0.8 V positive unselected bit line voltage to the bit lines for the unselected columns and further discharges the bit line for the selected column to ground, and the source line biasing circuit applies the 0.8 V unselected source line voltage to the source lines for the unselected columns and further applies a 2.5 V selected source line voltage to the source line for the selected column, and
wherein, when the write operation is the erasing operation, the word line biasing circuit discharges the word line for the selected row to ground and further applies the 2.5 V unselected word line voltage to the word lines for the unselected rows, the bit line biasing circuit applies the 0.8 V unselected bit line voltage to the bit lines for the unselected columns and applies a 2.5 V selected bit line voltage to the bit line for the selected column, and the source line biasing circuit applies the 0.8 V unselected source line voltage to the source lines for the unselected columns and discharges the source line for the selected column to ground.

19. The structure of claim 14, wherein the programmable resistor is a resistive random-access memory-type programmable resistor.

20. The structure of claim 14, wherein the P-type field effect transistor is a standard gate dielectric transistor.
